(19) United States
(12) Patent Application Publication
(10) Pub. No.: US 2008/0266954 A1
(43) Pub. Date: Oct. 30, 2008

(54) Transition areas for dense memory arrays

(76) Inventors: Boaz Eitan, Hofit (IL); Rustom Irani, Santa Clara, CA (US); Assaf Shappir, Kiryat Ono (IL)

Correspondence Address: EMPK & Shiloh, LLP;c/o Landon IP, Inc., 1700 Diagonal Road, Suite 450, Alexandria, VA, 22314, US

(21) Appl. No.: 12/213,620

(22) Filed: Jun. 23, 2008

Related U.S. Application Data
(63) Continuation of application No. 12/149,202, filed on Apr. 29, 2008.
Application No. 12/149,202 is a continuation of application No. 11/604,029, filed on Nov. 24, 2006.
(60) Provisional application No. 60/739,426, filed on Nov. 25, 2005.
(60) Provisional application No. 60/800,022, filed on May 15, 2006.
(60) Provisional application No. 60/800,021, filed on May 15, 2006.

(51) Int. Cl. G11C 16/04; H01S 4/00

(52) U.S. Cl. 365/185.05; 29/592.1

(57) ABSTRACT

A non-volatile memory chip has word lines spaced a sub-F (sub-minimum feature size F) width apart with extensions of the word lines in at least two transition areas. Neighboring extensions are spaced at least F apart. The present invention also includes a method for word-line patterning of a non-volatile memory chip which includes generating sub-F word lines with extensions in transition areas for connecting to peripheral transistors from mask generated elements with widths of at least F.

### CROSS-REFERENCE TO RELATED APPLICATIONS

This application is a continuation application of U.S. Ser. No. 12/149,202 filed Apr. 29, 2008, which is a continuation of U.S. Ser. No. 11/604,029 filed Nov. 24, 2006 which claims benefit from U.S. Provisional Patent Application No. 60/739,426, filed Nov. 25, 2005, and U.S. Provisional Patent Application No. 60/800,022, filed May 15, 2006, and U.S. Provisional Patent Application No. 60/800,021, filed May 15, 2006, all of which are hereby incorporated in their entirety by reference.

### FIELD OF THE INVENTION

The present invention relates to extra dense, non-volatile memory arrays generally and to their connection to the periphery in particular.

### BACKGROUND OF THE INVENTION

Dual bit memory cells are known in the art. One such memory cell is the NROM (nitride read only memory) cell 10, shown in FIG. 1A to which reference is now made, which stores two bits 12 and 14 in a nitride based layer 16, such as an oxide-nitride-oxide (ONO) stack, sandwiched between a polysilicon word line 18 and a channel 20. Channel 20 is defined by buried bit line diffusions 22 on each side which are isolated from word line 18 by a thermally grown or deposited oxide layer 26, grown/deposited after bit lines 22 are implanted. During thermal drives, bit lines 22 may diffuse sideways, expanding from the implantation area.

A dual polysilicon process (DPP) may also be used to create an NROM cell. FIG. 1B, to which reference is now made, shows such a cell. A first polysilicon layer is deposited over nitride based layer 16 and is etched in columns 19 between which bit lines 22 are implanted. Word lines 18 are then deposited as a second polysilicon layer, cutting columns 19 of the first polysilicon layer into islands between bit lines 22. Before creating the second polysilicon layer, bit line oxides 26 are deposited between polysilicon columns 19, rather than grown as previously done.

NROM cells are described in many patents, for example in U.S. Pat. No. 6,649,972, assigned to the common assignees of the present invention. Where applicable, descriptions involving NROM are intended specifically to include related oxide-nitride technologies, including SONOS (Silicon-Oxide-Nitride-Oxide-Silicon), MNOS (Metal-Nitride-Oxide-Silicon), MONOS (Metal-Oxide-Nitride-Oxide-Silicon) and the like used for NVM devices. Further description of NROM and related technologies may be found at “Non Volatile Memory Technology”, 2005 published by Saifun Semiconductor, and materials presented at and through http://siliconnexus.com, “Design Considerations in Scaled SONOS Nonvolatile Memory Devices” found at: http://klabs.org/richcontent/MemoryContent/nvmt_symp/nvmts_{—}2000/presentations/bu_white_sonos_lehigh_univ.pdf,

“SONOS Nonvolatile Semiconductor Memories for Space and Military Applications” found at: http://klabs.org/richcontent/MemoryContent/nvmt_symp/nvmts_{—}2000/papers/adams_d.pdf, “Philips Research-Technologies-Embedded Nonvolatile Memories” found at: http://research.philips.com/technologies/ics/nvmemories/index.htnl, and “Semiconductor Memory: Non-Volatile Memory (NVM)” found at: http://ece.nus.edu.sg/stfpage/elezhucx/myweb/NVM.pdf, all of which are incorporated by reference herein in their entirety.

As shown in FIG. 2, to which reference is now briefly made, NROM technology employs a virtual-ground array architecture with a dense crisscrossing of word lines 18 and bit lines 22. Word lines 18 and bit lines 22 optimally can allow a 4 F² size cell, where F designates the minimum feature size of an element of the chip for the technology in which the array was constructed. For example, the feature size for a 65 nm technology is F=65 nm.

U.S. patent application Ser. Nos. 11/489,327 and 11/489,747 describe a novel architecture and manufacturing process to generate a very dense array with very closely spaced word lines. In this array, the cells are less than 4 F² in size. The minimum theoretical size of the cells is 2 F².

### SUMMARY OF THE PRESENT INVENTION

An object of the present invention is to improve upon the prior art.

There is therefore provided, in accordance with a preferred embodiment of the present invention, a non-volatile memory chip with word lines spaced a sub-F (sub-minimum feature size F) width apart, and extensions of the word lines in at least two transition areas, wherein neighboring said extensions in at least one of said transition areas are spaced at least F apart.

There is also provided in accordance with a preferred embodiment of the present invention a non-volatile memory chip including word lines in a memory array with spacings between neighboring word lines of less than half the width of one of the word lines and extensions of the word lines in at least two transition areas wherein neighboring said extensions in at least one of said transition areas are spaced more than the width of one word line apart.

Further in accordance with a preferred embodiment of the present invention, the transition areas are on different sides of an array of the word lines.

Still further, in accordance with a preferred embodiment of the present invention, array is a NROM (nitride read only memory) array.

Additionally, in accordance with a preferred embodiment of the present invention, the extensions are insulated from each other by a dielectric filler.

Moreover, in accordance with a preferred embodiment of the present invention, the extensions are connected to peripheral transistors.

Further in accordance with a preferred embodiment of the present invention, the dielectric filler is at least one of oxide or oxynitride.

Still further, in accordance with a preferred embodiment of the present invention, the extensions are formed of conductive materials such as tungsten, salicide or silicide.

Additionally, in accordance with an alternative embodiment of the present invention, the extensions are formed of polysilicon.

Moreover, in accordance with a preferred embodiment of the present invention, the extensions are integral to said word lines.

There is also provided in accordance with a preferred embodiment of the present invention, a non-volatile memory chip with a densely packed array with spacings between neighboring word lines of less than half the width of one of said word lines, a loosely packed periphery, and at least two transition areas connecting word lines of the densely packed array to the loosely packed periphery, wherein each transition area connects only a portion of the word lines.

Further in accordance with a preferred embodiment of the present invention, each portion is every other word line.

Still further, in accordance with a preferred embodiment of the present invention, the extensions of said every other word lines are integral to said word lines.

There is also provided in accordance with a preferred embodiment of the present invention, a method for word-line patterning of a non-volatile memory chip, the method including generating sub-F word lines with extensions in transition areas for connecting to peripheral transistors from mask generated elements with widths of at least a minimum feature size F.

Additionally, in accordance with a preferred embodiment of the present invention, the generating includes generating a first set of rows from the mask generated elements, and generating a second set of rows, interleaved between the first set of rows, from the first set of rows.

Moreover, in accordance with a preferred embodiment of the present invention, first generating includes creating rows of nitride hard mask where each row has a width of greater than 1 F, depositing word line material between the rows, etching the word line material from a first transition area, etching the rows from a second transition area, and depositing oxide into the etched areas.

Further in accordance with a preferred embodiment of the present invention, the second generating includes etching the nitride hard mask, depositing nitride spacers in place of the rows of nitride, and depositing word line material between the spacers.

Still further, in accordance with a preferred embodiment of the present invention, the second transition area is generally located on an opposite side of the word lines from the first transition area.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIGS. 1A and 1B are schematic illustrations of two types of NROM cell;

FIG. 2 is a schematic illustration of a prior art non-volatile memory array;

FIG. 3 is a schematic illustration of a novel non-volatile memory array, constructed and operative in accordance with a preferred embodiment of the present invention;

FIG. 4 is form a flow chart illustration of a method for creating the array of FIG. 3; and

FIGS. 5A, 5B, 5C, 5D, 5E, 5F, 5G, 5H and 5I are schematic illustrations of the array at different stages during the method of FIGS. 4A and 4B.

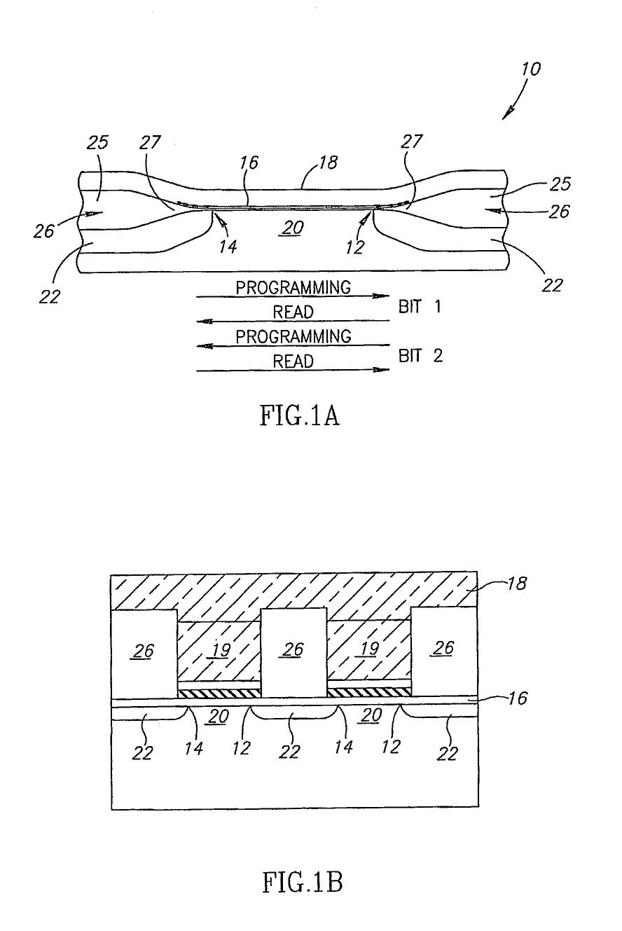

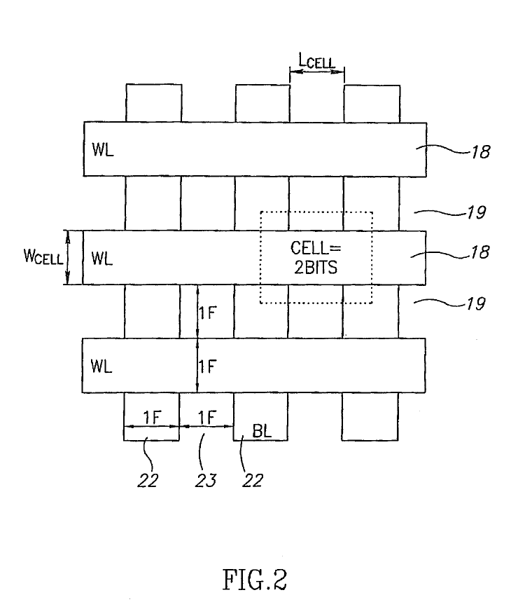

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE PRESENT INVENTION

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

Applicants have realized that, while densely packed word lines may provide small cells, they are difficult to connect to the transistors of the periphery, since the periphery transistors are typically much larger and thus, the periphery is typically much more loosely packed.

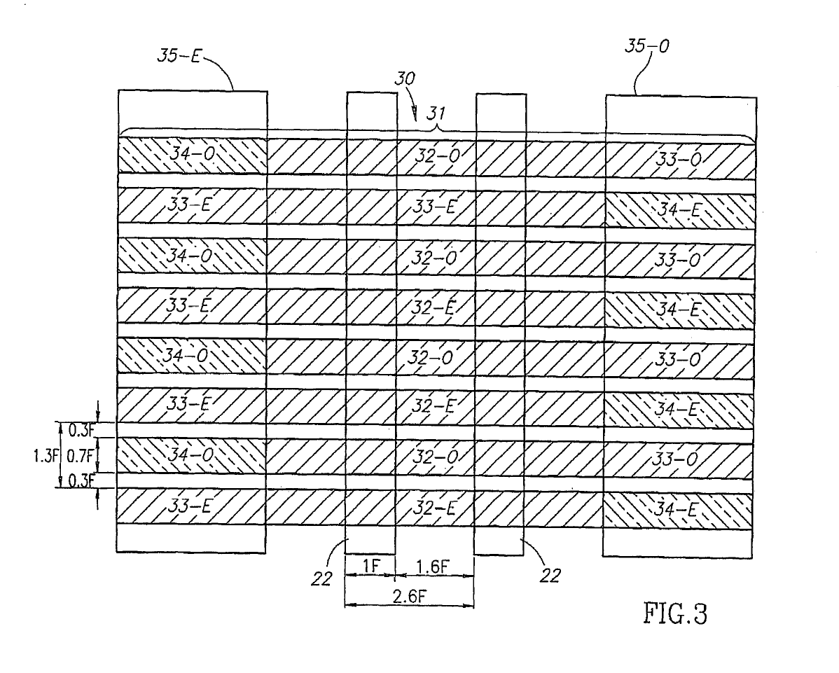

Reference is now made to FIG. 3, which schematically illustrates an exemplary non-volatile memory chip 28 with a densely packed, memory array 30, constructed and operative in accordance with a preferred embodiment of the present invention Memory array 30 comprises bit lines 22 intersected by word lines 32, with “fan-out” areas 35-E and 35-O. Fan-out areas 35 may be transition areas where array elements such as word lines 32 may connect to their associated transistors in a periphery area (not shown). In exemplary array 30, word line 32 may be a width of 0.7 F and may be spaced a distance of 0.3 F. These widths and spacings are only exemplary; as discussed in U.S. Ser. No. 11/489,327 and Ser. No. 11/489,747, many other widths and spacings are possible, all of which are sub-F (i.e. less than the minimum feature size F).

In accordance with a preferred embodiment of the present invention, word lines 32 may be formed from rows 31, where rows 31 may comprise word lines 32, active extensions 33 and insulating extensions 34. Extensions 33 and 34 may extend into their respective fan-out areas, as described in more detail hereinbelow.

In accordance with a preferred embodiment of the present invention, each fan-out area may control a portion of word lines 32. For example, fan-out area 35-E may control the even word lines, labeled 32-E, and fan-out area 35-O may control the odd word line rows, labeled 32-O. As shown in FIG. 3, only even word line rows 32-E may extend into even fan-out area 35-E with active extensions 33-E while only odd word line rows 32-O may extend into odd fan-out area 35-O with active extensions 33-O. Because of the alternating word lines 32, within fan-out areas 35-E and 35-O, the spacing between active extensions 33 may be larger than the minimum feature size 1 F (in FIG. 3, a spacing of 1.3 F is shown), thereby ensuring that the periphery transistors may easily connect to the word lines 32 they are to control.

As discussed in U.S. Ser. No. 11/489,327 and Ser. No. 11/489,747, word lines may be generated from one another. Only one set, for example the even word lines, may be laid down in a lithographic process. The second set, for example the odd word lines, may be generated from the first set through a series of self-aligning processes. In the present invention, rows 31 may be laid down in a similar manner, with one set of rows being laid down lithographically and the second set of rows being generated from the first set.

In accordance with a preferred embodiment of the present invention and as discussed hereinbelow, insulating extensions 34, formed of insulating material such as oxide or oxynitride, may be generated at the ends of those word lines 32 that do not extend into each fan-out area 35. Thus, even word lines 32-E may have insulating extensions 34-E in odd fan-out area 35-O while odd word lines 32-O may have insulating extensions 34-O in even fan-out area 35-O.

The remainder of this application will describe how to create fan-out areas 35 while creating densely packed, memory array 30.

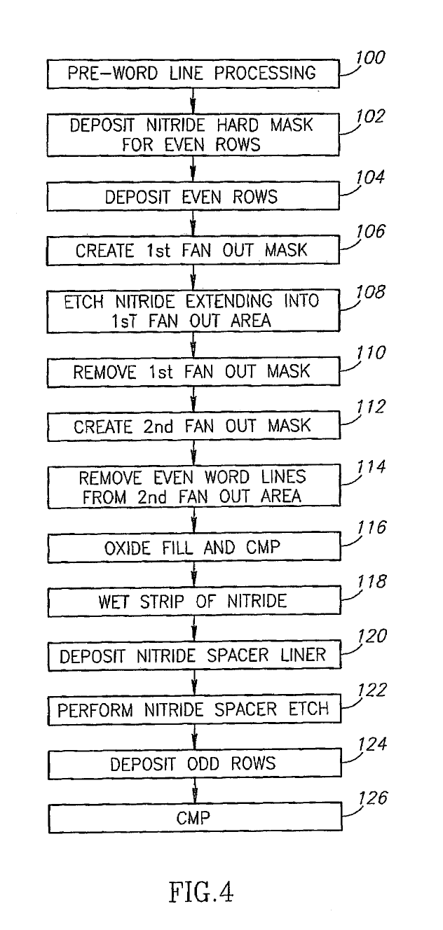

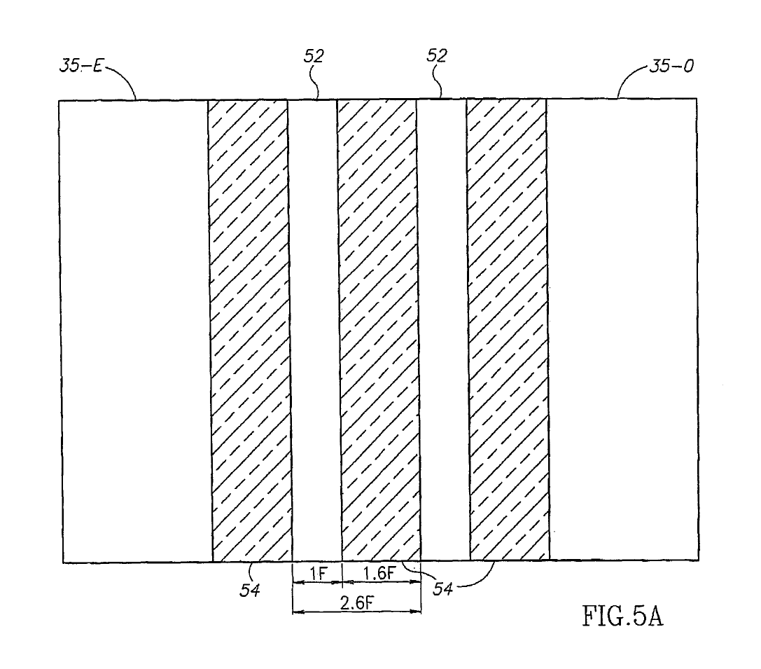

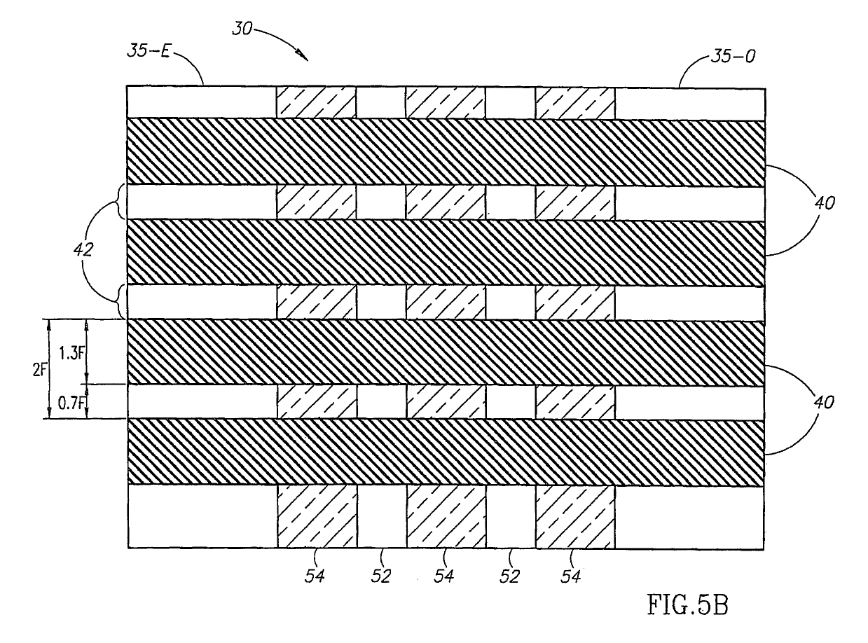

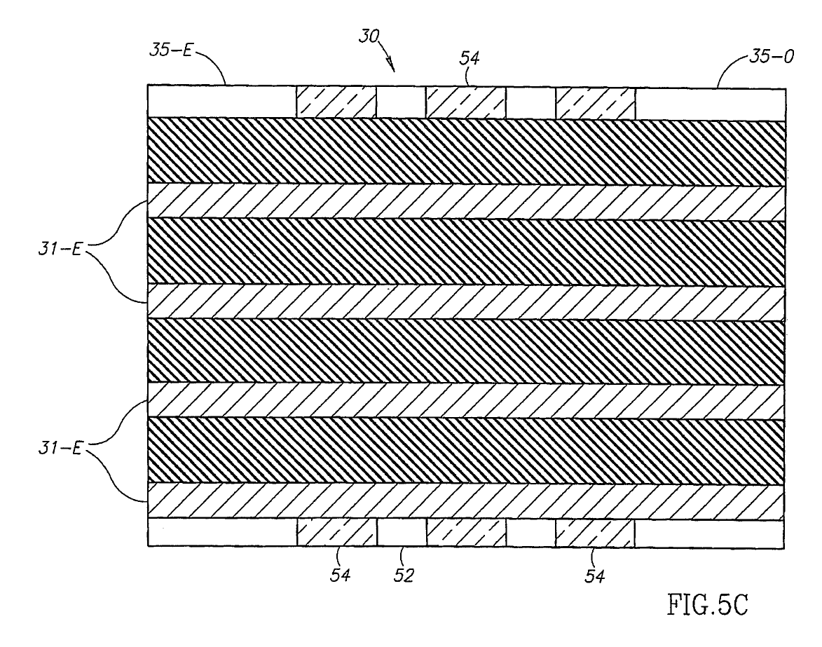

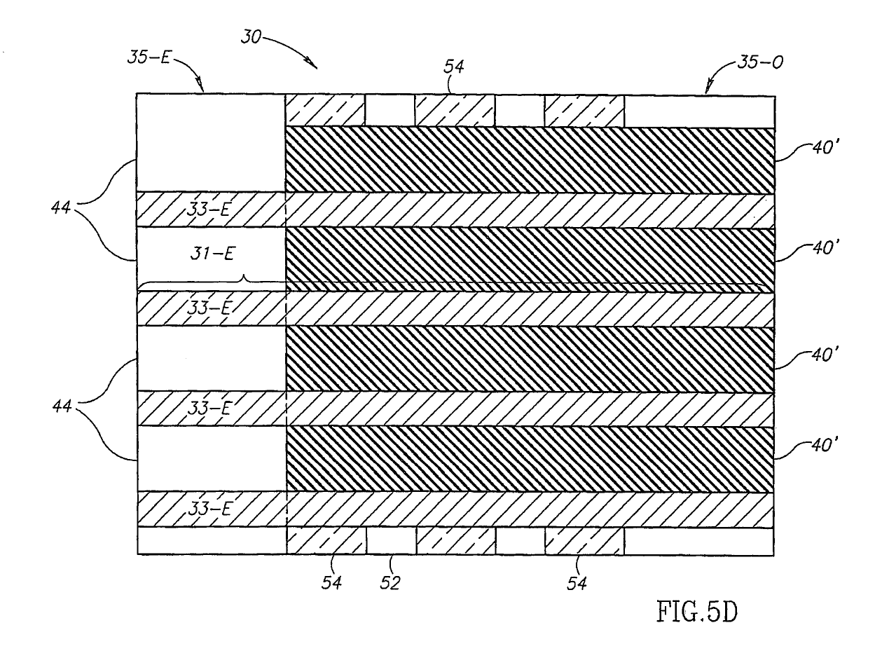

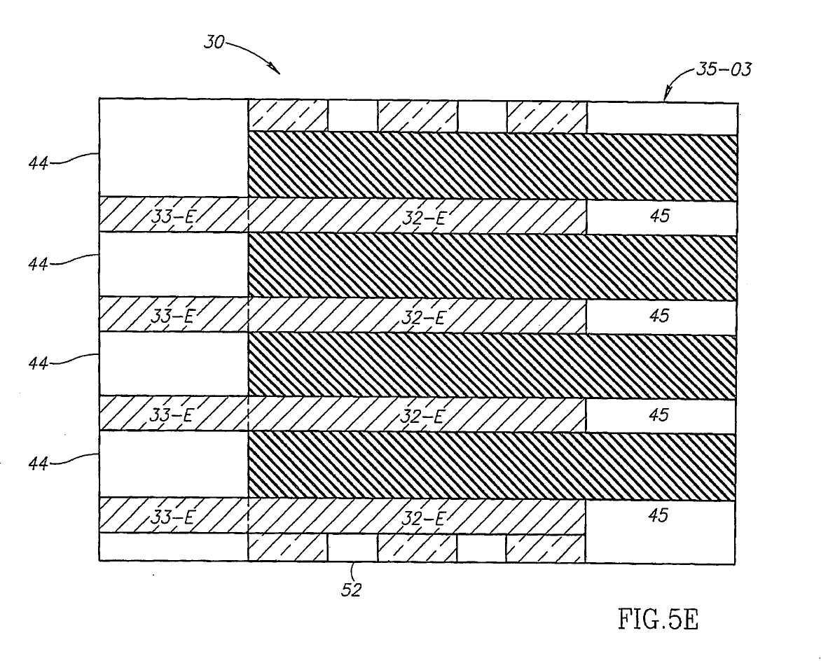

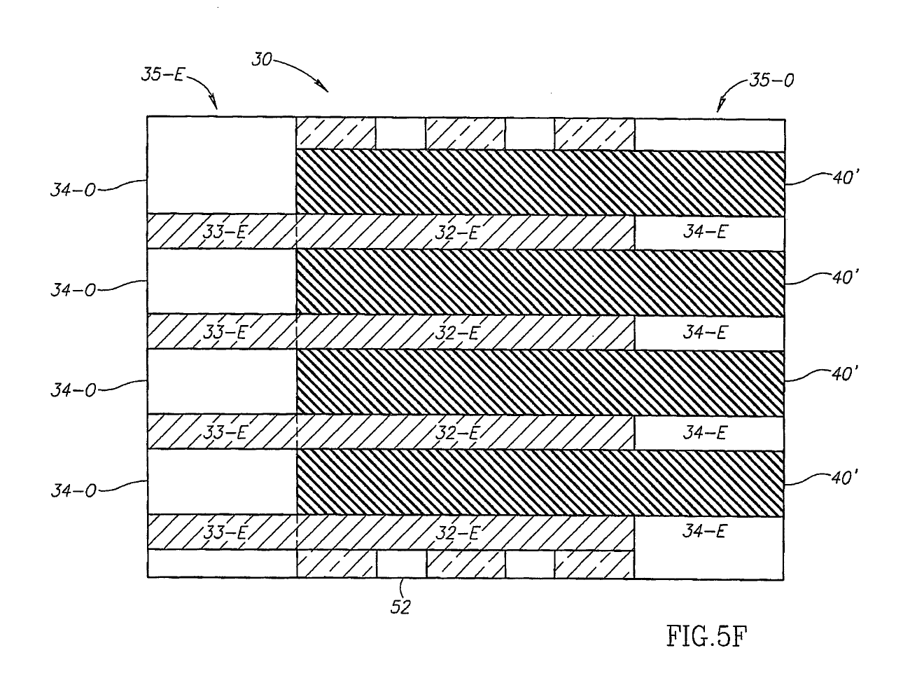

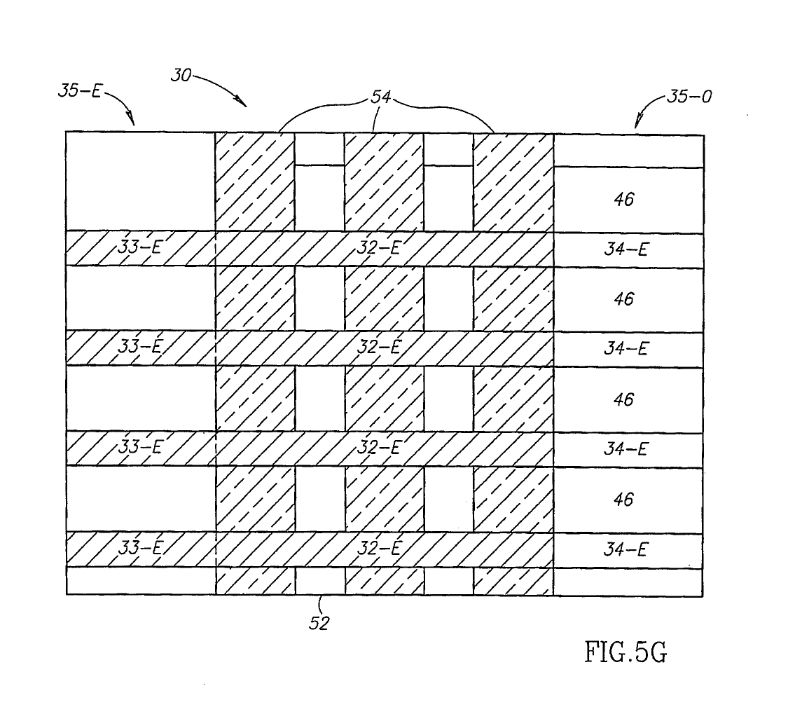

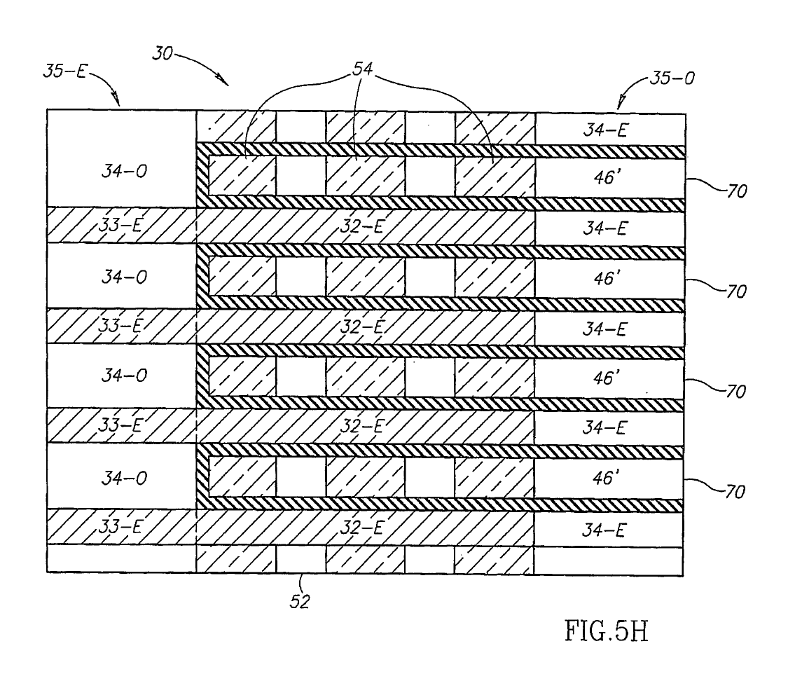

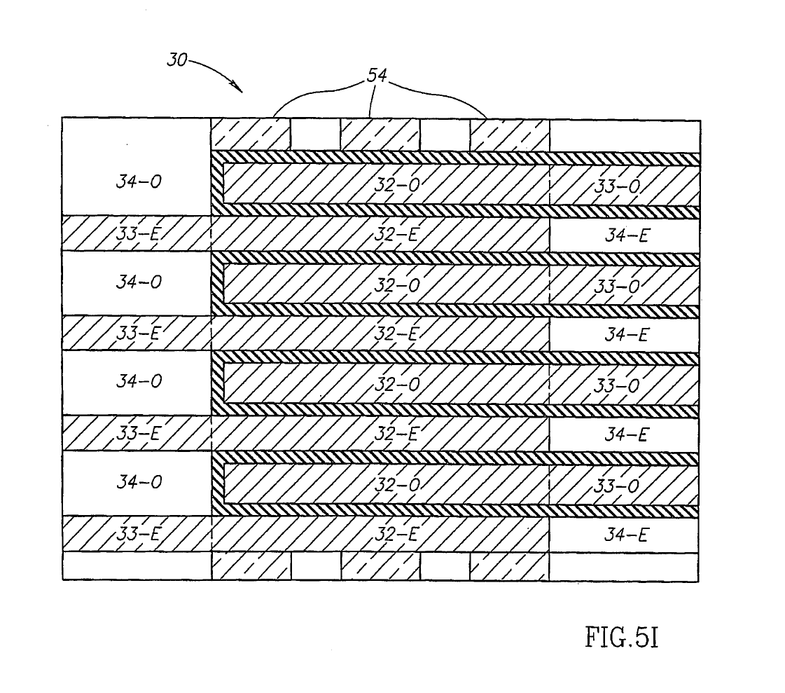

Reference is now made to FIG. 4, which illustrates how the creation of fan-out areas 35 may be included as a part of a process for creating memory array 30, described in U.S. patent application Ser. No. 11/489,327 and Ser. No. 11/489,747, assigned to the common assignees of the present invention. Reference is also made to FIGS. 5A-5I, which illustrate various steps within the process of FIG. 4.

The process begins, in step 100, with the process steps prior to word line patterning. Suitable DPP type process steps may be found in U.S. patent application Ser. Nos. 11/489,327 and 11/489,747, as well as the following applications assigned to the common assignees of the present invention, all of which applications are incorporated herein by reference: U.S. patent application Ser. No. 11/247,733, filed Oct. 11, 2005, U.S. patent application Ser. No. 11/336,093 filed Jan. 20, 2006 and U.S. patent application Ser. No. 11/440,624, filed May 24, 2006.

The results of step 100 are illustrated in FIG. 5A. Alternating columns of polysilicon 54 and bit line oxides 52 may be visible. These columns may be bracketed by fan-out areas 35-E and 35-O, which may be of oxide or of active material or both. In accordance with a preferred embodiment of the present invention, bit line oxides 52 may have widths of 1 F and may cover previously implanted bit lines (FIG. 3). Polysilicon columns 54 may have widths of 1.6 F and fan-out areas 35 may have widths greater than or equal to the bit line pitch. For FIG. 5, fan-out areas 35 are about 3 F wide. The chip may also be planarized to provide a flat, uniform surface for word line processing.

As shown in FIG. 5B, a nitride hard mask 40 may then be deposited (step 102—FIG. 4) in parallel rows that are generally orthogonal to the columns of bit line oxides 52 and polysilicon 54. In accordance with an exemplary embodiment of the present invention, nitride rows 40 (after nitride spacer formation) may have a width of 1.3 F and spacings 42 between them may have a width of 0.7 F, thus resulting in a combined pitch of 2 F without violating the constraints for lithographic operations.

Material may then be deposited (step 104—FIG. 4) between nitrides 40 in spacings 42 in order to create rows 31 (later to become word lines 32 and their extensions 33 and 34) in array 30 and fan-out areas 35. In accordance with a preferred embodiment of the present invention, the material may be conductive, such as tungsten. However, other suitable materials, conductive or semi-conductive, may be used as well, including, for example, cobalt salicide, polysilicon, other salicides, tungsten or silicide. FIG. 5C illustrates the results of step 104. Even rows 31-E may have been deposited in spacings 42 (FIG. 5B) between nitride rows 40.

The memory chip may then be planarized to provide a smooth surface and a set of fan out steps (steps 106-126) may be performed. These steps may generate fan out areas 35 where insulating extensions 34 (FIG. 3) may alternate with extensions 33 of word lines 32. Even fan out area 35-E may only have active extensions 33-E of even word lines 32-E, whereas odd fan out area 35-O may only have active extensions 33-O of odd word lines 32-O (FIG. 3). Accordingly, insulating extensions 34-O and 34-E in fan-out areas 35-E and 35-O, respectively, may be askew with each other.

Initially, a first fan out mask may be created (step 106). Even fan out area 35-E may be exposed, while the rest of the memory chip (including memory array 30 and fan-out area 35-O) may be covered. A nitride etch may be performed (step 108) which may etch out elements of nitride rows 40 in exposed fan out area 35-E, leaving active extensions 33-E of rows 31-E. FIG. 5D illustrates the results of step 108. Exposed fan-out areas 44, which may be exposed elements of fan-out areas 35-E (FIG. 5A), may now be visible where the portions of nitride rows 40 may have been etched out of fan out area 35-E. The remaining portions of the etched nitride rows are now labeled 40′.

The first fan out mask may then be removed (step 110) and a second fan out mask created (step 112). Fan out area 35-O may be exposed, while the rest of the chip may be covered. A word line etch, etching the material used for rows 31, while not etching the nitride, may be performed (step 114) which may etch out elements of rows 31-E extending into exposed fan out area 35-O. FIG. 5E illustrates the results of step 114. Exposed fan out areas 45, which may be exposed elements of fan-out oxide 35-O (FIG. 5A), may now be visible where extending elements of rows 31-E may have been etched out of fan out area 35-O. It will be appreciated that word lines 32-E and their active extensions 33-E have been created as has been an area 45 for their insulating extension 34-E.

It will also be appreciated that portions of exposed fan out areas 44 and 45 may have been partially etched during steps 108 and 114. However, as will be described hereinbelow, exposed fan out areas 44 and 45 may now be covered with an oxide, and accordingly there may be no lasting effect from such partial etches.

As mentioned hereinabove, an oxide fill may then deposited (step 116), completely covering the memory chip and filling exposed fan-out areas 44 and 45, thereby creating insulating extensions 34-O and 34-E, respectively. The memory chip may then be planarized to the level of word lines 32-E, their active extensions 33-E and nitride rows 40′. The results of step 116 may be illustrated by FIG. 5F. Insulating extensions 34-O may now cover exposed fan-out areas 44 (FIG. 5D) between even active extensions 33-E in fan out area 35-E. Similarly, insulating extensions 34-E may now cover exposed fan-out areas 45 (FIG. 5E) between nitride rows 40′ in fan out area 35-O.

The process may then continue with non-fan-out steps. Nitride rows 40′ may be removed (step 118) using a wet strip. FIG. 5G may illustrate the results of step 118. Previously covered elements of bit line oxides 52, polysilicon columns 54, and elements 46 of fan out area 35-O may have been exposed.

A nitride liner may now be deposited (step 120) in the area formerly occupied by nitride rows 40 (FIG. 5G), covering previously exposed bit line oxides 52, exposed fan out areas 46, and polysilicon columns 54. A nitride spacer etch may be performed (step 122), exposing once again elements of bit-line oxides 52 and exposed fan-out areas 46, as well as polysilicon columns 54. FIG. 5H may illustrate the results of steps 120 and 122. Nitride spacers 70 may line the area previously occupied by nitride rows 40′ (FIG. 5F) and may form a perimeter lining word lines 32-E, their insulating extensions 34-E and a portion of odd insulating extensions 34-O.

It will be appreciated that the width of spacers 70 may be 0.3 F. Accordingly, in accordance with a preferred embodiment of the present invention, “troughs” defined by spacers 70 may have a width of 0.7 F which may be generally equal to the width of even word lines 32-E. Other widths for spacers 70 are possible and are incorporated in the present invention.

Word line row material may then be deposited (step 124) between spacers 70. As discussed hereinabove, the material may be semi-conductive (such as polysilicon) or conductive (such as tungsten, salicide or silicide). The memory chip may then be planarized (step 126) to provide a smooth surface. FIG. 5I illustrates the results of steps 122-126. Odd word lines 32-O and their active extensions 33-O may have been formed inside the “troughs” defined by spacers 70, thus covering the previously exposed elements of bit line oxides 52, polysilicon columns 54 and fan-out areas 35-O (FIG. 5G).

At this point, the process for creating the fan out area required for densely packed memory cell 30 may be complete. U.S. patent application Ser. Nos. 11/489,327 and 11/489,747 may detail further steps required to finish the creation of the memory chip.

It will be appreciated that the memory chip as represented in FIG. 5I may be a densely packed memory cell. In this example, word lines 32-E and 32-O may both have widths of 0.7 F, and they may be separated from each other by spacers 70 with a width of 0.3 F. Accordingly, memory array 30 may have a word line pitch of one word line for every 1 F. As mentioned hereinabove, these widths and spacings are only exemplary; many other widths and spacings are possible, all of which are sub-F (i.e. less than the minimum feature size F).

It will further be appreciated that while even word lines 32-E extend into fan out area 35-E with active extensions 33-E, they do not extend into fan out area 35-O. Similarly, odd word lines 32-O extend into fan out area 35-O with active extensions 33-O, but do not extend into fan out area 35-E. Accordingly, each set of word lines 32 may have sufficient space to properly connect to the transistors of the periphery.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

What is claimed is:

1. A non-volatile memory (“nvm”) array segment comprising:
a set of nvm cells electrically connected to one another; and
a first wordline connected to a first cell and a second wordline connected to a second cell,
wherein said first and second wordlines are produced non-concurrently.

2. A non-volatile memory (“nvm”) array segment comprising:
a set of nvm cells; and
a first set of wordlines and a second set of wordlines interlaced with the first set of wordlines, such that a wordline of the first set is adjacent to a wordline of the second set, wherein a parameter of a wordline in the first set is measurably more similar to a corresponding parameter of another wordline from the first set than to a corresponding parameter of another wordline from the second set.

3. The NVM array segment according to claim 2, wherein the parameter is selected from the group of parameters consisting of width, height, thickness, hardness, resistivity, conductivity, impedance, capacitance, chemical composition, dopant concentration and ion concentration.

4. A non-volatile memory (“nvm”) array segment comprising:
a set of nvm cells; and
a first set of wordlines and a second set of wordlines interlaced with the first set of wordlines, such that a wordline of the first set is adjacent to a wordline of the second set, wherein spacing between a first pair of adjacent wordlines is different from spacing between a second pair of adjacent wordlines.

5. The segment according to claim 4, wherein a wordline of the first set is closer to a first adjacent wordline of the second set than it is to a second adjacent wordline of the second set.

6. A non-volatile memory (“nvm”) array segment comprising:
a set of nvm cells electrically interconnected, said cells separated at least partially by a shallow trench isolation material of a given width between adjacent cells; and
wherein a pitch between adjacent wordlines is less than 95 percent of the given width of the shallow trench isolation material.

7. The non-volatile memory (“nvm”) array segment of claim 6, wherein the pitch between adjacent wordlines is less than 90 percent of the given width of the shallow trench isolation material.

8. The non-volatile memory (“nvm”) array segment of claim 6, wherein the pitch between adjacent wordlines is less than 85 percent of the given width of the shallow trench isolation material.

9. The non-volatile memory (“nvm”) array segment of claim 6, wherein the pitch between adjacent wordlines is less than 80 percent of the given width of the shallow trench isolation material.

10. A non-volatile memory (“nvm”) array segment produced at least partially using a lithographic mask having wordline apertures, said nvm segment comprising:
a set of nvm cells and a set of wordlines,
wherein a number of wordlines in the set of wordlines is greater than the number of wordline apertures in the mask.

11. The nvm array segment according to claim 10, wherein the number of wordlines in the set is approximately double the number of wordline apertures in the mask.

12. A non-volatile memory (“nvm”) array segment comprising:
a set of nvm cells; and
a set of wordlines,
wherein a spacing between two adjacent cells connected to a wordline is greater than a pitch between two adjacent wordlines.
